(19) United States
(12) Patent Application Publication
(10) Pub. No.: US 2025/0127005 A1
(43) Pub. Date: Apr. 17, 2025

(54) DISPLAYING BASE PLATE AND DISPLAY PANEL

(71) Applicant: BOE Technology Group Co., Ltd., Beijing (CN)

(72) Inventors: Kuo Shen, Beijing (CN); Xinxing Guan, Beijing (CN)

(73) Assignee: BOE Technology Group Co., Ltd., Beijing (CN)

(21) Appl. No.: 18/578,359

(22) PCT Filed: Mar. 31, 2023
(86) PCT No.: PCT/CN2023/085361

§ 371 Date: Jan. 11, 2024

(51) Int. Cl. H10K 59/35

(52) U.S. Cl. CPC H10K 59/353

(57) ABSTRACT

A displaying base plate and a display panel are provided by the present application. The displaying base plate includes a substrate, and a plurality of pixel units that are located within an active area of the substrate and are arranged in an array, and each of at least some of the pixel units includes two first sub-pixels, two second sub-pixels and at least one third sub-pixel; the two first sub-pixels are located at a same pair of diagonal-corner positions of a virtual quadrilateral, and the two second sub-pixels are located at the other pair of diagonal-corner positions of the virtual quadrilateral; and an orthographic projection of the third sub-pixel on the substrate and a region circled by an orthographic projection of the virtual quadrilateral on the substrate at least partially overlap.

### TECHNICAL FIELD

The present application relates to the technical field of displaying and, more particularly, to a displaying base plate and a display panel.

### BACKGROUND

With the development of the technology of displaying, consumers have higher and higher requirements on the effect of displaying of display products. Therefore, the slight display problems existing in the display process are also difficult to be accepted by the market and consumers.

In the related art, display products such as notebooks, tablets and on-board displays mainly employ the traditional mode of the arrangement of the red, green and blue pixels; for example, the red sub-pixels or the green sub-pixels are separately arranged into a row. In this way, in a specific display screen, color edge appears at the edge of the active area of the display products, the effect of displaying is reduced.

### SUMMARY

The embodiments of the present application employ the following technical solutions:

In the first aspect, a displaying base plate is provided by an embodiment of the present application, wherein the displaying base plate includes a substrate, and a plurality of pixel units that are located within an active area of the substrate and are arranged in an array, and each of at least some of the pixel units includes two first sub-pixels, two second sub-pixels and at least one third sub-pixel; and
the two first sub-pixels are located at a same pair of diagonal-corner positions of a virtual quadrilateral, and the two second sub-pixels are located at the other pair of diagonal-corner positions of the virtual quadrilateral; and an orthographic projection of the third sub-pixel on the substrate and a region circled by an orthographic projection of the virtual quadrilateral on the substrate at least partially overlap.

In at least one embodiment of the present application, the orthographic projection of the third sub-pixel on the substrate is located within the region circled by the orthographic projection of the virtual quadrilateral on the substrate.

In at least one embodiment of the present application, the orthographic projection of the third sub-pixel on the substrate and the region circled by the orthographic projection of the virtual quadrilateral on the substrate partially overlap.

In at least one embodiment of the present application, the virtual quadrilateral is a virtual trapezoid, the two first sub-pixels include a first primary sub-pixel and a first auxiliary sub-pixel, and the two second sub-pixels include a second primary sub-pixel and a second auxiliary sub-pixel; and
the first primary sub-pixel, the second auxiliary sub-pixel, the first auxiliary sub-pixel and the second primary sub-pixel are sequentially located at four vertex-angle positions of the virtual trapezoid, and the third sub-pixel is located at a bottom edge of the virtual trapezoid, and is disposed at a same row as the second auxiliary sub-pixel and the first auxiliary sub-pixel.

In at least one embodiment of the present application, the active area includes a center region and an edge region surrounding the center region, and the edge region includes at least one ring of sub-pixels; when the displaying base plate is displaying a frame, parts of the first auxiliary sub-pixel and the second auxiliary sub-pixel that are located within the edge region are configured to maintain a lightening state; and parts of the first auxiliary sub-pixel and the second auxiliary sub-pixel that are located
within the center region are configured to maintain a dark state; or parts of the first auxiliary sub-pixel and the second auxiliary sub-pixel that are located within the center region are configured to maintain a lightening state.

In at least one embodiment of the present application, the active area includes a center region and an edge region surrounding the center region;
each of parts of the pixel units that are located within the edge region includes two first sub-pixels, two second sub-pixels and at least one third sub-pixel; and
each of parts of the pixel units that are located within the center region includes one first sub-pixel, one second sub-pixel and one third sub-pixel; and within the center region, the first sub-pixel, the second sub-pixel and the third sub-pixel are located sequentially at three vertex angles of a virtual triangle.

In at least one embodiment of the present application, an area of an orthographic projection of the first primary sub-pixel on the substrate is greater than an area of an orthographic projection of the first auxiliary sub-pixel on the substrate; and an area of an orthographic projection of the second primary sub-pixel on the substrate is greater than an area of an orthographic projection of the second auxiliary sub-pixel on the substrate.

In at least one embodiment of the present application, patterns of orthographic projections of sub-pixels on the substrate include a polygon, an arc shape or a combination of a polygon and an arc shape; and
when the patterns of the orthographic projections of the sub-pixels on the substrate include the polygon, an edge of one side of the first auxiliary sub-pixel away from the second auxiliary sub-pixel and an edge of the second primary sub-pixel away from the first primary sub-pixel are substantially collinear; and an edge of one side of the second auxiliary sub-pixel away from the first auxiliary sub-pixel and an edge of one side of the first primary sub-pixel away from the second primary sub-pixel are substantially collinear.

In at least one embodiment of the present application, the virtual quadrilateral is a virtual rectangle, and the orthographic projection of the third sub-pixel on the substrate partially overlaps with orthographic projections on the substrate of two opposite side edges of the virtual rectangle; and
each of the pixel units includes one third sub-pixel, and a center point of the third sub-pixel and an intersection point of diagonal lines of the virtual rectangle substantially coincide.

In at least one embodiment of the present application, the virtual quadrilateral is a virtual rectangle, each of the pixel units includes two third sub-pixels, and orthographic projections of two third sub-pixels on the substrate partially overlap with orthographic projections on the substrate of two opposite side edges of the virtual rectangle; and
a center of symmetry of the two third sub-pixels and an intersection point of diagonal lines of the virtual rectangle substantially coincide.

In at least one embodiment of the present application, both of orthographic projections on the substrate of center points of the two third sub-pixels are located within a region circled by an orthographic projection of the virtual rectangle on the substrate.

In at least one embodiment of the present application, the displaying base plate further includes a plurality of data lines, and within a region where a same pixel unit is located, there is a gap between the two third sub-pixels, and orthographic projections of at least some of the data lines on the substrate fall within a region where the gap is located.

In at least one embodiment of the present application, an orthographic projection on the substrate of an intersection point of diagonal lines of the virtual quadrilateral falls within a region of the orthographic projection of the third sub-pixel on the substrate; and center points of the pixel units fall within a region where the third sub-pixel is located.

In at least one embodiment of the present application, a center point of each of the pixel units and a center point of the third sub-pixel substantially coincide.

In at least one embodiment of the present application, in a direction from a center point of the third sub-pixel pointing to an outer contour of the third sub-pixel, distances from the two first sub-pixels to the third sub-pixel are substantially equal, distances from the two second sub-pixels to the third sub-pixel are substantially equal, and the distances from the first sub-pixels to the third sub-pixel are substantially equal to the distances from the second sub-pixels to the third sub-pixel.

In at least one embodiment of the present application, an outer contour of the orthographic projection of the third sub-pixel on the substrate is substantially circular; and outer contours of orthographic projections of the first sub-pixels and the second sub-pixels on the substrate are a pattern formed by a combination of a polygon and an arc shape, and patterns of the outer contours of the orthographic projections of the first sub-pixels and the second sub-pixels on the substrate are same.

In at least one embodiment of the present application, areas of orthographic projections of the two first sub-pixels on the substrate are substantially equal, and areas of orthographic projections of the two second sub-pixels on the substrate are substantially equal.

In at least one embodiment of the present application, patterns of orthographic projections on the substrate of the at least some of the pixel units are a central symmetric pattern.

In at least one embodiment of the present application, the first sub-pixels are red sub-pixels, the second sub-pixels are green sub-pixels, and the third sub-pixel is a blue sub-pixel.

In the second aspect, a display panel is provided by an embodiment of the present application, wherein the display panel includes the displaying base plate according to any one of the embodiments in the first aspect.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the related art, the figures that are required to describe the embodiments or the related art will be briefly described below. Apparently, the figures that are described below are merely embodiments of the present application, and a person skilled in the art can obtain other figures according to these figures without paying creative work.

FIGS. 1A-1B are the designs of the pixel units of a displaying base plate in the related art; and

FIGS. 2A-13 are the designs of the pixel units of the fourteen types of displaying base plates according to the embodiments of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first”, “second”, “third” and “fourth” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the terms that indicate orientation or position relations, such as “upper” and “lower”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation on the present application.

In the description of the present disclosure, the terms “one embodiment”, “some embodiments”, “exemplary embodiments”, “example”, “specific example” or “some examples” are intended to indicate that specific features, structures, materials or characteristics related to the embodiment or example are included in at least one embodiment or example of the present application. The illustrative indication of the above terms does not necessarily refer to the same one embodiment or example. Moreover, the specific features, structures, materials or characteristics may be included in any one or more embodiments or examples in any suitable manner.

In the embodiments of the present application, the meaning of “plurality of” is “two or more”, and the meaning of “at least one” is “one or more”, unless explicitly and particularly defined otherwise.

All of the features used in the embodiments of the present application of “substantially collinear”, “substantially overlapping”, “substantially parallel”, “substantially perpendicular”, “substantially the same” and so on include the features of “collinear”, “overlapping”, “parallel”, “perpendicular”, “the same” and so on in the strict sense, and include the cases of a certain tolerance, taking into consideration the measurement and the tolerances relevant to the measurement on particular quantities (for example, limited by the measuring system), and represent that they are within the acceptable deviation ranges of the particular values determined by a person skilled in the art. For example, the “substantially” can represent that they are within one or more standard deviations, or within 10% or 5% of the values.

Unless stated otherwise in the context, throughout the description and the claims, the term “include” is interpreted as the meaning of opened containing, i.e., “including but not limited to”.

The polygons used herein are not polygons in strict sense, may be an approximate triangle, parallelogram, trapezoid, pentagon, hexagon and so on, and may have some tiny deformations caused by tolerances.

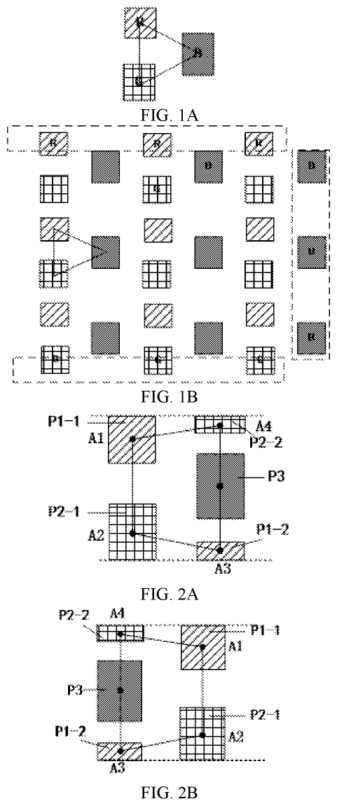

In the related art, display products such as notebooks, tablets and on-board displays mainly employ the traditional mode of the arrangement of the red (R), green (G) and blue (B) pixels shown in FIG. 1A. For example, as shown by the region marked by the dotted-line block in FIG. 1B, the sub-pixels of one color (red sub-pixels, green sub-pixels or blue sub-pixels) are separately arranged into rows. Accordingly, in particular displayed frames, the problem of color edge appears at the edge of the active area of the display products, for example, problems of red color edge and green color edge (because the emitted-light brightness of the blue sub-pixels is lower than the brightness of the red sub-pixels and the brightness of the green sub-pixels, blue color edge cannot easily be perceived by human eyes), thus the effect of displaying is significantly reduced.

Currently, it is urgently needed to provide further solutions, to optimize the effect of displaying of the displaying device.

In view of the above, a displaying base plate and a display panel are provided by the embodiments of the present application, by configuring that each of at least some of the pixel units of the displaying base plate includes at least five sub-pixels (two first sub-pixels, two second sub-pixels and at least one third sub-pixel), and by configuring that the two first sub-pixels are located at the same pair of diagonal-corner positions of a virtual quadrilateral, and the two second sub-pixels are located at the other pair of diagonal-corner positions of the virtual quadrilateral; and the orthographic projection of the third sub-pixel on the substrate and the region circled by the orthographic projection of the virtual quadrilateral on the substrate at least partially overlap, after color mixing of the light rays emitted by the two first sub-pixels located at the same pair of diagonal corners and the two second sub-pixels located at the other pair of the diagonal corners, the colors of the light rays can be neutralized, thereby the problem that color edge appears at the edge of the active area of the displaying base plate is ameliorated to a large extent, and the effect of displaying is improved.

The displaying base plate and the display panel will be explained and described particularly below in combination with the drawings.

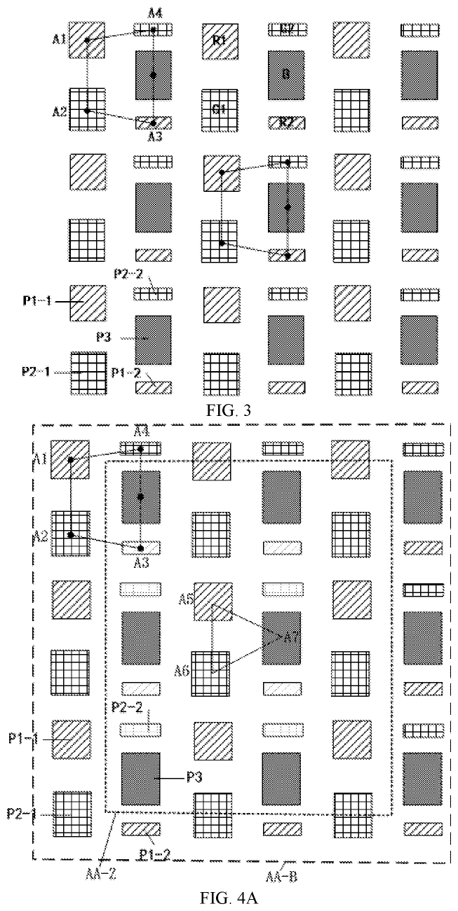

A displaying base plate is provided by an embodiment of the present application, wherein the displaying base plate includes a substrate, and a plurality of pixel units that are located within an active area AA of the substrate and are arranged in an array. As shown in FIGS. 2-13, and each of at least some of the pixel units includes two first sub-pixels P1, two second sub-pixels P2 and at least one third sub-pixel P3. The two first sub-pixels P1 are located at the same pair of diagonal-corner positions of a virtual quadrilateral A1A2A3A4, and the two second sub-pixels P2 are located at the other pair of diagonal-corner positions of the virtual quadrilateral A1A2A3A4. The orthographic projection of the third sub-pixel P3 on the substrate and the region circled by the orthographic projection of the virtual quadrilateral A1A2A3A4 on the substrate at least partially overlap.

The active area (AA) refers to the region used to display frames. The light emitting region (also referred to as a pixel opening region) refers to the region in the sub-pixel where the light rays exit. The situation of the distribution of the sub-pixels in the displaying base plate are illustrated in all of the figures according to the embodiments of the present application with the pixel opening region as the representative.

The “at least some of the pixel units” refer to some of the pixel units of the displaying base plate or all of the pixel units of the displaying base plate.

It should be noted that the two first sub-pixels P1 in the above “two first sub-pixels” have the same color, but the shapes and the sizes of the two first sub-pixels P1 are not limited. In some embodiments, the colors, the structures and the sizes of the two first sub-pixels P1 may be completely the same. In some other embodiments, the colors of the two first sub-pixels P1 are the same, and the structures and the sizes are not necessarily the same. The similar expressions in the present application (for example, two second sub-pixels P2 and two third sub-pixels P3) are the same as the above-described situation, which is not discussed further in the following.

The above-described “located” generally refers to that the center points of the sub-pixels (P1, P2 and P3) substantially coincide at the diagonal corners of the virtual quadrilateral A1A2A3A4.

The center point of each of the sub-pixels may be the geometric center of the pattern of the sub-pixel, and may also be the center of the light emitting region of the sub-pixel. The center of the light emitting region refers to the position having the highest luminous intensity. The meanings of the “center point” at the other positions in the present application are similar to the above-described situation, and are not discussed further.

The above-described one group of diagonal corners refer to the two diagonal corners located in the same one diagonal line of the virtual quadrilateral.

In an exemplary embodiment, the shapes of the sub-pixels may be polygons, for example, regular polygons such as a triangle, a quadrangle and a pentagon. Alternatively, the shapes of the sub-pixels may be polygons having at least one rounded corner, for example, a rounded-corner quadrangle and a rounded-corner pentagon. Alternatively, the shapes of the sub-pixels may be irregular shapes obtained by removing or adding a part based on polygons.

In an exemplary embodiment, the shapes of the sub-pixels may be arc shapes, for example, a circular shape, an elliptical shape, a semicircular shape and a semi-elliptical shape.

In an exemplary embodiment, the virtual quadrilateral described above may be a virtual trapezoid, a virtual rectangle, a virtual rhombus or a virtual parallelogram.

It should be noted that the virtual shapes according to the embodiments of the present application, for example, the virtual quadrilateral described above, and the virtual trapezoid, the virtual triangle and the virtual rectangle described below, do not exist actually, and are merely concepts that are proposed in order to facilitate to describe the position relation of the sub-pixels.

In the embodiments of the present application, two neighboring virtual quadrilaterals do not overlap, and there is a gap between the two neighboring virtual quadrilateral.

That the orthographic projection of the third sub-pixel P3 on the substrate and the region circled by the orthographic projection of the virtual quadrilateral A1A2A3A4 on the substrate at least partially overlap includes but is not limited to the following cases:

In the first case, in at least one embodiment of the present application, the orthographic projection of the third sub-pixel P3 on the substrate is located within the region circled by the orthographic projection of the virtual quadrilateral A1A2A3A4 on the substrate.

That the orthographic projection of the third sub-pixel P3 on the substrate is located within the region circled by the orthographic projection of the virtual quadrilateral A1A2A3A4 on the substrate means that the outer contour of the orthographic projection of the third sub-pixel P3 on the substrate is located within the outer contour of the region circled by the orthographic projection of the virtual quadrilateral A1A2A3A4 on the substrate, or the outer contour of the orthographic projection of the third sub-pixel P3 on the substrate and the outer contour of the region circled by the orthographic projection of the virtual quadrilateral A1A2A3A4 on the substrate partially overlap.

In addition, that the outer contour of the orthographic projection of the third sub-pixel P3 on the substrate is located within the outer contour of the region circled by the orthographic projection of the virtual quadrilateral A1A2A3A4 on the substrate may further include, for example, that the orthographic projection of the third sub-pixel P3 on the substrate is located at the center region of the region circled by the orthographic projection of the virtual quadrilateral A1A2A3A4 on the substrate. Preferably, the orthographic projection of the third sub-pixel P3 on the substrate is located at the center point of the region circled by the orthographic projection of the virtual quadrilateral A1A2A3A4 on the substrate.

The center region of the region circled by the orthographic projection of the virtual quadrilateral A1A2A3A4 on the substrate refers to the region of the virtual quadrilateral A1A2A3A4 that contains the center point of the virtual quadrilateral other than the regions of its side edges.

In the second case, in at least one embodiment of the present application, the orthographic projection of the third sub-pixel P3 on the substrate and the region circled by the orthographic projection of the virtual quadrilateral A1A2A3A4 on the substrate partially overlap.

That the orthographic projection of the third sub-pixel P3 on the substrate and the region circled by the orthographic projection of the virtual quadrilateral A1A2A3A4 on the substrate partially overlap may include that the orthographic projection of the center point of the third sub-pixel P3 on the substrate is located on the orthographic projections on the substrate of the side edges of the virtual quadrilateral A1A2A3A4, or the orthographic projection of the center point of the third sub-pixel P3 on the substrate is located within the region circled by the orthographic projection of the virtual quadrilateral A1A2A3A4 on the substrate.

The meaning of the center point of the third sub-pixel P3 is similar to the preceding context, and is not discussed further herein.

It should be noted that, no matter how the sub-pixels in the same one pixel unit are arranged, gaps exist between each two of the three types of sub-pixels, to prevent cross-color.

The colors of each two of the first sub-pixels P1, the second sub-pixels P2 and the third sub-pixel P3 are different. As an example, the colors of the first sub-pixels P1, the second sub-pixels P2 and the third sub-pixel P3 are one of the red color, the green color and the blue color individually.

For example, the first sub-pixels P1 are red sub-pixels, the second sub-pixels P2 are green sub-pixels, and the third sub-pixel P3 is a blue sub-pixel. Alternatively, the first sub-pixels P1 are blue sub-pixels, the second sub-pixels P2 are red sub-pixels, and the third sub-pixel P3 is a green sub-pixel. Alternatively, the first sub-pixels P1 are green sub-pixels, the second sub-pixels P2 are blue sub-pixels, and the third sub-pixel P3 is a red sub-pixel. Alternatively, the first sub-pixels P1 are red sub-pixels, the second sub-pixels P2 are blue sub-pixels, and the third sub-pixel P3 is a green sub-pixel. Alternatively, the first sub-pixels P1 are blue sub-pixels, the second sub-pixels P2 are green sub-pixels, and the third sub-pixel P3 is a red sub-pixel. Those may be decided particularly according to practical design demands. The embodiments of the present application are illustrated by taking the case as an example in which the first sub-pixels P1 are red sub-pixels, the second sub-pixels P2 are green sub-pixels, and the third sub-pixel P3 is a blue sub-pixel.

The type of the displaying base plate is not limited herein. As an example, the displaying base plate may be an organic light emitting diode (OLED) displaying base plate. Alternatively, the displaying base plate may also be a white organic light emitting diode (WOLED) displaying base plate. Alternatively, the displaying base plate may also be a liquid crystal display (LCD) displaying base plate.

In the embodiments of the present application, by configuring that each of at least some of the pixel units of the displaying base plate includes at least five sub-pixels (the two first sub-pixels P1, the two second sub-pixels P2 and the at least one third sub-pixel P3), and by configuring that the two first sub-pixels P1 of the same color are located at the same pair of diagonal-corner positions of a virtual quadrilateral A1A2A3A4, and the two second sub-pixels P2 of the same color are located at the other pair of diagonal-corner positions of the virtual quadrilateral A1A2A3A4; and the orthographic projection of the third sub-pixel P3 on the substrate and the region circled by the orthographic projection of the virtual quadrilateral A1A2A3A4 on the substrate at least partially overlap, after color mixing of the light rays emitted by the two first sub-pixels P1 located at the same pair of diagonal corners and the two second sub-pixels P2 located at the other pair of the diagonal corners, the colors of the light rays can be neutralized, thereby the problem that color edge appears at the edge of the active area of the displaying base plate is ameliorated to a large extent, and the effect of displaying is improved.

In at least one embodiment of the present application, as shown in FIGS. 2A, 2B, 3, 4A, 5, 6 and 7, the virtual quadrilateral A1A2A3A4 is a virtual trapezoid, the two first sub-pixels P1 include a first primary sub-pixel P1-1 and a first auxiliary sub-pixel P1-2, and the two second sub-pixels P2 include a second primary sub-pixel P2-1 and a second auxiliary sub-pixel P2-2. The first primary sub-pixel P1-1, the second auxiliary sub-pixel P2-2, the first auxiliary sub-pixel P1-2 and the second primary sub-pixel P2-1 are sequentially located at the four vertex-angle positions of the virtual trapezoid, and the third sub-pixel P3 is located at the bottom edge of the virtual trapezoid, and is disposed at the same row as the second auxiliary sub-pixel P2-2 and the first auxiliary sub-pixel P1-2.

In an exemplary embodiment, the virtual trapezoid may be an isosceles trapezoid. At this moment, the distance from the center of the first primary sub-pixel P1-1 to the center of the second auxiliary sub-pixel P2-2 is equal to the distance from the center of the second primary sub-pixel P2-1 to the center of the first auxiliary sub-pixel P1-2.

In an exemplary embodiment, that the third sub-pixel P3 is located at the bottom edge of the virtual trapezoid may include two cases: that the third sub-pixel P3 is located at the upper bottom edge of the virtual trapezoid, or that the third sub-pixel P3 is located at the lower bottom edge of the virtual trapezoid. The figures according to the embodiments of the present application are drew and illustrated by taking the case as an example in which the third sub-pixel P3 is located at the lower bottom edge of the virtual trapezoid and is disposed at the same row as the second auxiliary sub-pixel P2-2 and the first auxiliary sub-pixel P1-2.

In an exemplary embodiment, the upper bottom edge and the lower bottom edge of the virtual trapezoid are parallel, wherein the upper bottom edge refers to the bottom edge of a lower length, the lower bottom edge refers to the bottom edge of a higher length, and the length of the lower bottom edge is greater than the length of the upper bottom edge.

The above-described “disposed at the same row” refers to that the center points of the third sub-pixel P3, the second auxiliary sub-pixel P2-2 and the first auxiliary sub-pixel P1-2 are located substantially in the same one straight line. For example, the geometric centers of the third sub-pixel P3, the second auxiliary sub-pixel P2-2 and the first auxiliary sub-pixel P1-2 are located substantially in the same one straight line. Alternatively, the luminescence centers of the third sub-pixel P3, the second auxiliary sub-pixel P2-2 and the first auxiliary sub-pixel P1-2 are located substantially in the same one straight line.

The colors of the first primary sub-pixel P1-1 and the first auxiliary sub-pixel P1-2 are the same. The colors of the second primary sub-pixel P2-1 and the second auxiliary sub-pixel P2-2 are the same. It is not limited herein whether the shapes and the sizes (the areas) of the first primary sub-pixel P1-1 and the first auxiliary sub-pixel P1-2 are the same and whether the shapes and the sizes of the second primary sub-pixel P2-1 and the second auxiliary sub-pixel P2-2 are the same.

In some embodiments, as shown in FIGS. 2A, 2B, 3, 4A, 5, 6 and 7, the area of the first primary sub-pixel P1-1 is greater than the area of the first auxiliary sub-pixel P1-2. Alternatively, in some other embodiments, the area of the first primary sub-pixel P1-1 is equal to the area of the first auxiliary sub-pixel P1-2.

In some embodiments, as shown in FIGS. 2A, 2B, 3, 4A, 5, 6 and 7, the area of the second primary sub-pixel P2-1 is greater than the area of the second auxiliary sub-pixel P2-2. Alternatively, in some other embodiments, the area of the second primary sub-pixel P2-1 is equal to the area of the second auxiliary sub-pixel P2-2.

In some embodiments, the area of the first primary sub-pixel P1-1 is equal to the area of the second primary sub-pixel P2-1.

In some embodiments, the area of the first auxiliary sub-pixel P1-2 is equal to the area of the second auxiliary sub-pixel P2-2.

In some embodiments, the area of the first primary sub-pixel P1-1 is less than the area of the second primary sub-pixel P2-1, and the area of the second primary sub-pixel P2-1 is less than the area of the third sub-pixel P3.

In some embodiments, all of the areas of the first primary sub-pixel P1-1, the second auxiliary sub-pixel P2-2, the first auxiliary sub-pixel P1-2 and the second primary sub-pixel P2-1 are equal.

In the displaying base plate according to the embodiments of the present application, by configuring that the first primary sub-pixel P1-1, the second auxiliary sub-pixel P2-2, the first auxiliary sub-pixel P1-2 and the second primary sub-pixel P2-1 are sequentially located at the four vertex-angle positions of the virtual trapezoid, and the third sub-pixel P3 is located at the bottom edge of the virtual trapezoid, and is disposed at the same row as the second auxiliary sub-pixel P2-2 and the first auxiliary sub-pixel P1-2, in this way, the same one row of the sub-pixels have at least two different colors. In an aspect, after color mixing of the light rays emitted by the two first sub-pixels P1 located at the same pair of diagonal corners and the two second sub-pixels P2 located at the other pair of the diagonal corners, the colors of the light rays can be neutralized. In another aspect, after color mixing of the light rays emitted by the sub-pixels in the same one row and having at least two colors, the colors of the light rays can be neutralized, thereby the problem that color edge appears at the edge of the active area AA of the displaying base plate is ameliorated to a large extent, and the effect of displaying is improved.

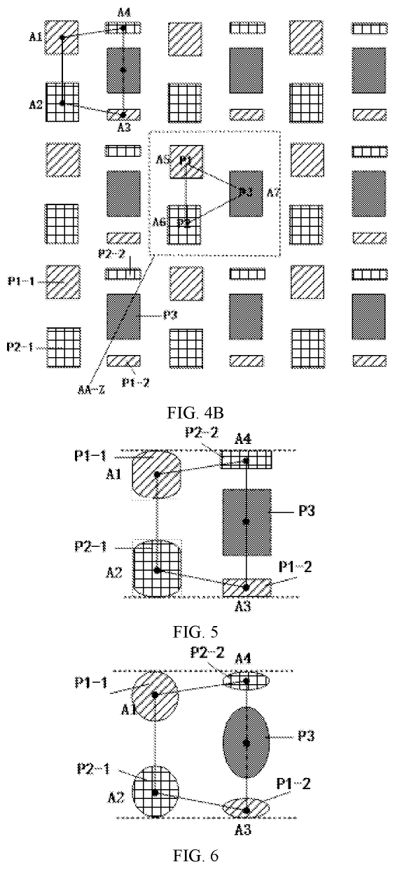

In at least one embodiment of the present application, as shown in FIG. 4A, the active area AA includes a center region AA-Z and an edge region AA-B surrounding the center region AA-Z, and the edge region AA-B includes at least one ring of sub-pixels. When the displaying base plate is displaying a frame, the parts of the first auxiliary sub-pixel P1-2 and the second auxiliary sub-pixel P2-2 that are located within the edge region AA-B are configured to maintain the lightening state. The parts of the first auxiliary sub-pixel P1-2 and the second auxiliary sub-pixel P2-2 that are located within the center region AA-Z are configured to maintain a dark state. Alternatively, the parts of the first auxiliary sub-pixel P1-2 and the second auxiliary sub-pixel P2-2 that are located within the center region AA-Z are configured to maintain the lightening state.

In an exemplary embodiment, as shown in FIG. 4A, it may be configured that each of all of the pixel units of the displaying base plate includes two first sub-pixels P1, two second sub-pixels P2 and at least one third sub-pixel P3. Because the problem of color edge usually happens at the edge of the active area AA, it is configured that, when the displaying base plate is displaying a frame, the parts of the first auxiliary sub-pixel P1-2 and the second auxiliary sub-pixel P2-2 that are located within the edge region are controlled by using a pixel driving circuit to maintain the lightening state, thus, after color mixing of the light rays emitted by the sub-pixels in the same one row and having two colors, the colors of the light rays can be neutralized, thereby the problem that color edge appears at the edge of the active area AA of the displaying base plate is ameliorated, and the effect of displaying is improved.

In addition, according to the demands on the aperture ratio of display products, when the displaying base plate is displaying a frame, the first auxiliary sub-pixel P1-2 and the second auxiliary sub-pixel P2-2 within the center region AA-Z of the active area AA may be controlled by using a pixel driving circuit to maintain the lightening state or the dark state, which, while ameliorating the problem of color edge, achieves the purpose of switching the aperture ratio. When the first auxiliary sub-pixel P1-2 and the second auxiliary sub-pixel P2-2 within the center region AA-Z of the active area AA maintain the lightening state, the aperture ratio of the displaying base plate is increased. When the first auxiliary sub-pixel P1-2 and the second auxiliary sub-pixel P2-2 within the center region AA-Z of the active area AA maintain the dark state, the aperture ratio within the center region AA-Z of the active area AA maintains unchanged. It should be noted that, if the aperture ratio of the displaying base plate is increased, the transmittance of the displaying base plate is increased, the effect of displaying is improved, the energy consumption is reduced, and the cost is reduced.

In at least one embodiment of the present application, the active area AA includes a center region AA-Z and an edge region AA-B surrounding the center region AA-Z. Each of some of the pixel units includes at least five sub-pixels (for example, five sub-pixels in FIGS. 2A, 2B, 5, 6, 8 and 12, or six sub-pixels in FIG. 9), for example, two first sub-pixels P1, two second sub-pixels P2 and at least one third sub-pixel P3. Each of some of the pixel units includes three sub-pixels, for example, one first sub-pixel P1, one second sub-pixel P2 and one third sub-pixel P3.

In an exemplary embodiment, as shown in FIG. 4B, each of the parts of the pixel units that are located within the edge region AA-B includes two first sub-pixels P1, two second sub-pixels P2 and at least one third sub-pixel P3. Each of the parts of the pixel units that are located within the center region AA-Z includes one first sub-pixel P1, one second sub-pixel P2 and one third sub-pixel P3. Within the center region AA-Z, the first sub-pixel P1, the second sub-pixel P2 and the third sub-pixel P3 are located sequentially at the three vertex angles of a virtual triangle A5A6A7.

In an exemplary embodiment, the centers of the first sub-pixel P1, the second sub-pixel P2 and the third sub-pixel P3 are located at the three vertex angles of the virtual triangle A5A6A7.

In an exemplary embodiment, the virtual triangle A5A6A7 may be an isosceles triangle. For example, the distance (the lateral edge A5A7) from the center of the first sub-pixel P1 to the center of the third sub-pixel P3 is equal to the distance (the lateral edge A6A7) from the center of the second sub-pixel P2 to the center of the third sub-pixel P3.

In an exemplary embodiment, the virtual triangle A5A6A7 may be an equilateral triangle. For example, all of the distance (the lateral edge A5A7) from the center of the first sub-pixel P1 to the center of the third sub-pixel P3, the distance (the lateral edge A6A7) from the center of the second sub-pixel P2 to the center of the third sub-pixel P3 and the distance (the lateral edge A5A6) from the center of the first sub-pixel P1 to the center of the second sub-pixel P2 are equal.

The center point of each of the sub-pixels refers to the geometric center or the luminescence center.

In the displaying base plate according to the embodiments of the present application, by configuring that each of some of the pixel units includes at least five sub-pixels, and each of some of the pixel units includes three sub-pixels, for example the each of the parts of the pixel units that are located within the edge region AA-B includes two first sub-pixels P1, two second sub-pixels P2 and at least one third sub-pixel P3; and each of the parts of the pixel units that are located within the center region AA-Z includes one first sub-pixel P1, one second sub-pixel P2 and one third sub-pixel P3, in this way, the at least five sub-pixels in the pixel units within the edge region AA-B can ameliorate the problem that color edge appears at the edge of the active area of the displaying base plate, to improve the effect of displaying. The design that the pixel units of the center region AA-Z maintain three sub-pixels can satisfy the design demands on particular aperture ratios, thus the problem of color edge can be ameliorated while maintaining the aperture ratio substantially unchanged.

In at least one embodiment of the present application, as shown in FIGS. 2A, 2B, 5 and 6, the area of the orthographic projection of the first primary sub-pixel P1-1 on the substrate is greater than the area of the orthographic projection of the first auxiliary sub-pixel P1-2 on the substrate. The area of the orthographic projection of the second primary sub-pixel P2-1 on the substrate is greater than the area of the orthographic projection of the second auxiliary sub-pixel P2-2 on the substrate.

In an exemplary embodiment, the third sub-pixel P3 has the highest area among the sub-pixels of the three colors. When the third sub-pixel P3 is located between the first auxiliary sub-pixel P1-2 and the second auxiliary sub-pixel P2-2, and all of the three of them are disposed at the same row and are located at the bottom edge of the virtual trapezoid, by configuring that the area of the orthographic projection of the first primary sub-pixel P1-1 on the substrate is greater than the area of the orthographic projection of the first auxiliary sub-pixel P1-2 on the substrate; and the area of the orthographic projection of the second primary sub-pixel P2-1 on the substrate is greater than the area of the orthographic projection of the second auxiliary sub-pixel P2-2 on the substrate, the problem of interference caused by low spacing from the first auxiliary sub-pixel P1-2 and the second auxiliary sub-pixel P2-2 to the third sub-pixel P3 can be prevented to a large extent, thereby the effect of displaying is improved.

In at least one embodiment of the present application, the patterns of the orthographic projections of the sub-pixels on the substrate include a polygon, an arc shape or a combination of a polygon and an arc shape.

As an example, the polygon includes a triangle, a quadrangle, a pentagon, a hexagon and so on, the arc shape includes a sector shape, a circular shape, an elliptical shape, a semicircular shape, a semielliptical shape and so on, and the combination of a polygon and an arc shape includes a pattern formed by splicing a polygon and an arc shape and a pattern formed by removing part of the area from a polygon or an arc shape.

In some embodiments, as shown in FIGS. 2A, 2B, 3 and 4A, all of the shapes of the first primary sub-pixel P1-1, the second auxiliary sub-pixel P2-2, the first auxiliary sub-pixel P1-2 and the second primary sub-pixel P2-1 are the same and are a rectangle.

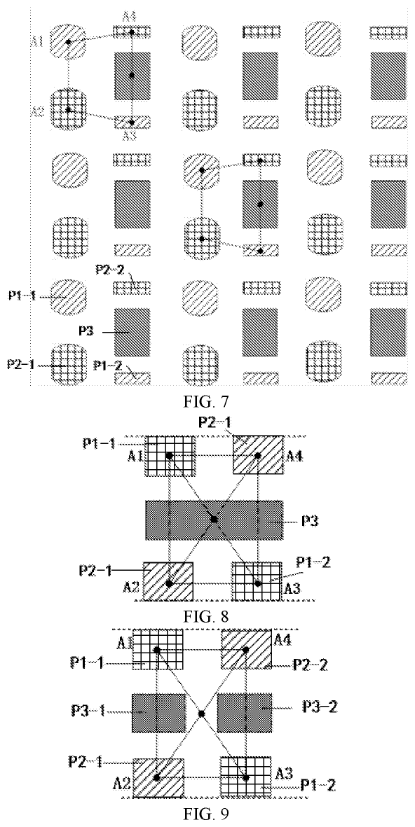

In some embodiments, as shown in FIGS. 5 and 7, the shapes of the first primary sub-pixel P1-1, the second auxiliary sub-pixel P2-2, the first auxiliary sub-pixel P1-2 and the second primary sub-pixel P2-1 are partially the same. For example, both of the first primary sub-pixel P1-1 and the second primary sub-pixel P2-1 are a pattern formed by splicing a polygon and an arc shape, and all of the shapes of the first auxiliary sub-pixel P1-2, the second auxiliary sub-pixel P2-2 and the third sub-pixel P3 are a rectangle.

In some embodiments, as shown in FIG. 6, all of the shapes of the first primary sub-pixel P1-1, the second auxiliary sub-pixel P2-2, the first auxiliary sub-pixel P1-2 and the second primary sub-pixel P2-1 are an arc shape, for example, a circular shape and an elliptical shape.

In an exemplary embodiment, the displaying base plate is an OLED displaying base plate, each of the sub-pixels of the displaying base plate includes a light filtering layer (CF, Color Filter) located at the side of the OLED luminescent layer (EML) away from the substrate, and the light filtering layer (CF, Color Filter) is integrated at the packaging layer. Such a technique is referred to as the technique of color on encapsulation (COE).

Regarding the OLED displaying base plates using the technique of COE, external light rays (for example, the ambient light) are easily reflected, which causes that the display panel fabricated by using the displaying base plate has chaotic color separation, to affect the effect of displaying.

The reason for the color separation will be explained below. When the display panel is in a state that the display panel is turned off, the external light rays emit white-color light beams to the display panel having a plurality of green sub-pixels and a plurality of red sub-pixels, a plurality of green sub-pixels form a green pixel matrix having a reflecting surface, and the reflecting surface is not parallel to the reflecting surface of the red pixel matrix formed by a plurality of red sub-pixels. The non-parallel pixel matrix may be attributed to various processes, wherein the processes include but are not limited to processes of fabricating the display panel and processes of curving the display panel. The ambient light beams reflected by the elements and the metal traces of the display panel are transmitted out of the display panel via different color filtering layers corresponding to different sub-pixels, so that the ambient light beams reflected out of the display panel can display different colors according to the different light filtering layers (CF, Color Filter) that transmit the ambient light beams. When the reflected ambient light beams are transmitted via one of the plurality of green sub-pixels, the reflected ambient light beams change into green reflected ambient light beams. When the reflected ambient light beams are transmitted via one of the plurality of red sub-pixels, the reflected ambient light beams change into red reflected ambient light beams. Because the reflecting surface of the green pixel matrix and the reflecting surface of the red pixel matrix are not parallel, the plurality of green reflected ambient light beams are transmitted in the direction deviating from the transmission direction of the plurality of red reflected ambient light beams, and the human eyes see a green light-source image and a red light-source image (for example, color separation), which causes color separation.

For the display panel of the COE technique, the light rays emitted by the luminescent layer, when passing through the light filtering layer and exiting, are diffracted to a certain extent, diffraction may aggravate the problem of the color separation.

When the shape of the same one sub-pixel has a high difference in different directions, the diffractions in different directions in the same one sub-pixel might be different due to the dimension difference in the different directions. As compared with the polygonal sub-pixels, the diffraction of the sub-pixels of the shapes of an arc shape or the combination of a polygon and an arc shape is much slighter, which alleviates the color separation.

In the displaying base plate according to the embodiments of the present application, it may be configured that the shapes of at least some of the first primary sub-pixel P1-1, the second auxiliary sub-pixel P2-2, the first auxiliary sub-pixel P1-2 and the second primary sub-pixel P2-1 include an arc shape and a combination of a polygon and an arc shape, for example, a circular shape and an elliptical shape. Accordingly, the diffractions of the same one sub-pixel in various directions can tend to be the same, which can significantly ameliorate the problem of color separation, the effect of displaying is improved.

If the patterns of the orthographic projections of the sub-pixels on the substrate include a polygon, as shown in FIGS. 2A and 2B, the edge of the side of the first auxiliary sub-pixel P1-2 away from the second auxiliary sub-pixel P2-2 and the edge of the second primary sub-pixel P2-1 away from the first primary sub-pixel P1-1 are substantially collinear (for example, at the dotted line at the lower side of FIG. 2A). The edge of the side of the second auxiliary sub-pixel P2-2 away from the first auxiliary sub-pixel P1-2 and the edge of the side of the first primary sub-pixel P1-1 away from the second primary sub-pixel P2-1 are substantially collinear (for example, at the dotted line at the upper side of FIG. 2A).

The expression of being substantially collinear of the edges may be referred to as edge flushing. It can be understood that, taking the pixel unit shown in FIG. 2A as an example, the side edges of the sides of the first primary sub-pixel P1-1 and the second auxiliary sub-pixel P2-2 that are away from the center points of the pixel unit are flush, and the side edges of the sides of the second primary sub-pixel P2-1 and the first auxiliary sub-pixel P1-2 that are away from the center points of the pixel unit are flush.

In some other embodiments, as shown in FIGS. 8, 9 and 12, it may also be configured that the edge of the side of the first auxiliary sub-pixel P1-2 away from the second auxiliary sub-pixel P2-2 and the edge of the second primary sub-pixel P2-1 away from the first primary sub-pixel P1-1 are substantially collinear (for example, at the dotted line of the lower side of FIG. 8). The edge of the side of the second auxiliary sub-pixel P2-2 away from the first auxiliary sub-pixel P1-2 and the edge of the side of the first primary sub-pixel P1-1 away from the second primary sub-pixel P2-1 are substantially collinear (for example, at the dotted line of the upper side of FIG. 8).

In the embodiments of the present application, both of the first auxiliary sub-pixel P1-2 and the second auxiliary sub-pixel P2-2 may be referred to as a compensating sub-pixel.

In the embodiments of the present application, by configuring that the side edges of the sides of the first primary sub-pixel P1-1 and the second auxiliary sub-pixel P2-2 that are away from the center points of the pixel unit are flush, and the side edges of the sides of the second primary sub-pixel P2-1 and the first auxiliary sub-pixel P1-2 that are away from the center points of the pixel unit are flush, the sub-pixels of the different colors can be disposed at positions close to the center point of the pixel unit, so that the distances from the edges of the sub-pixels of the different colors located at the positions of the outer contour of the pixel unit to the center point of the pixel unit tend to be equal to the largest extent, the effect of color mixing of the sub-pixels of the different colors of the same one pixel unit is further improved, and the problem of color edge is ameliorated.

In at least one embodiment of the present application, as shown in FIG. 8, the virtual quadrilateral A1A2A3A4 is a virtual rectangle, and the orthographic projection of the third sub-pixel P3 on the substrate partially overlaps with the orthographic projections on the substrate of two opposite side edges of the virtual rectangle. Each of the pixel units includes one third sub-pixel P3, and the center point of the third sub-pixel P3 and the intersection point of diagonal lines of the virtual rectangle substantially coincide.

That the orthographic projection of the third sub-pixel P3 on the substrate partially overlaps with the orthographic projections on the substrate of two opposite side edges of the virtual rectangle includes the following cases:

In the first case, the orthographic projection of the third sub-pixel P3 on the substrate partially overlaps with the orthographic projections on the substrate of the lateral edge A1A2 of the virtual rectangle and the lateral edge A3A4 of the virtual rectangle. At this moment, the extending direction of the third sub-pixel P3 intersects with the extending direction of the longer sides of the virtual rectangle.

In the second case, the orthographic projection of the third sub-pixel P3 on the substrate partially overlaps with the orthographic projections on the substrate of the lateral edge A1A4 of the virtual rectangle and the lateral edge A2A3 of the virtual rectangle. At this moment, the extending direction of the third sub-pixel P3 is the same as the extending direction of the longer sides of the virtual rectangle.

In addition, that the center point of the third sub-pixel P3 and the intersection point of diagonal lines of the virtual rectangle substantially coincide includes that the geometric center of the third sub-pixel P3 and the intersection point of the diagonal lines of the virtual rectangle substantially coincide, and/or that the luminescence center of the third sub-pixel P3 and the intersection point of the diagonal lines of the virtual rectangle substantially coincide.

In the displaying base plate according to the embodiments of the present application, by configuring that the two first sub-pixels P1 are disposed at one pair of the diagonal corners of the virtual rectangle, and the two second sub-pixels are disposed at the other pair of the diagonal corners of the virtual rectangle, and by configuring that the center point of the third sub-pixel P3 and the intersection point of diagonal lines of the virtual rectangle substantially coincide, the luminescence center of the pixel unit can fall within the region where the third sub-pixel P3 is located, so that the luminescence center of the pixel unit and the region of the center point of the third sub-pixel coincide, which improves the effect of light mixing of the sub-pixels of the different colors of the same one pixel unit to a large extent, thereby the problem of color cast is prevented, and the effect of displaying is improved.

In at least one embodiment of the present application, as shown in FIG. 9, the virtual quadrilateral A1A2A3A4 is a virtual rectangle, each of the pixel units includes two third sub-pixels P3, and the orthographic projections of the two third sub-pixels P3 on the substrate partially overlap with the orthographic projections on the substrate of two opposite side edges of the virtual rectangle. The two third sub-pixels P3 are symmetrically arranged, and the center of symmetry of the two third sub-pixels P3 and the intersection point of diagonal lines of the virtual rectangle substantially coincide.

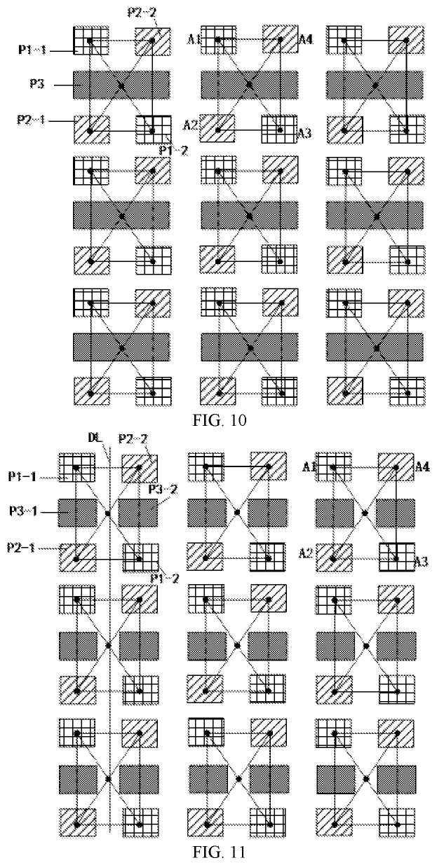

In an exemplary embodiment, as shown in FIGS. 9 and 11, both of the shapes and the sizes of the two third sub-pixels P3 are the same.

That the orthographic projections of the two third sub-pixels P3 on the substrate partially overlap with the orthographic projections on the substrate of two opposite side edges of the virtual rectangle includes the following cases:

In the first case, the orthographic projections of the two third sub-pixels P3 on the substrate individually partially overlap with the orthographic projections on the substrate of the lateral edge A1A2 of the virtual rectangle and the lateral edge A3A4 of the virtual rectangle. At this moment, the direction from one of the third sub-pixels P3 (for example, P3-1) pointing to the other of the third sub-pixels P3 (for example, P3-2) intersects with the extending direction of the longer sides of the virtual rectangle.

In the second case, the orthographic projections of the two third sub-pixels P3 on the substrate individually partially overlap with the orthographic projections on the substrate of the lateral edge A1A4 of the virtual rectangle and the lateral edge A2A3 of the virtual rectangle. At this moment, the direction from one of the third sub-pixels P3 (for example, P3-1) pointing to the other of the third sub-pixels P3 (for example, P3-2) is the same as the extending direction of the longer sides of the virtual rectangle.

The direction from one of the third sub-pixels P3 (for example, P3-1) pointing to the other of the third sub-pixels P3 (for example, P3-2) may be understood as the direction from the geometric center of one of the third sub-pixels P3 (for example, P3-1) pointing to the geometric center of the other of the third sub-pixels P3 (for example, P3-2).

In the displaying base plate according to the embodiments of the present application, by configuring that the two first sub-pixels P1 are disposed at one pair of the diagonal corners of the virtual rectangle, and the two second sub-pixels are disposed at the other pair of the diagonal corners of the virtual rectangle, the two third sub-pixels P3 are symmetrically arranged, and the center of symmetry of the two third sub-pixels P3 and the intersection point of diagonal lines of the virtual rectangle substantially coincide, the luminescence center of the pixel unit can fall adjacently to the position of the intersection point of the diagonal lines of the virtual rectangle, which improves the effect of light mixing of the sub-pixels of the different colors of the same one pixel unit to a large extent, thereby the problem of color cast is prevented, and the effect of displaying is improved.

In at least one embodiment of the present application, as shown in FIG. 9 or 11, both of the orthographic projections on the substrate of the center points of the two third sub-pixels P3 are located within the region circled by the orthographic projection of the virtual rectangle on the substrate. The center points include the geometric centers and the luminescence centers.

In an exemplary embodiment, both of the orthographic projections on the substrate of the geometric centers of the two third sub-pixels P3 are located within the region circled by the orthographic projection of the virtual rectangle on the substrate. At this moment, the area of the region where the third sub-pixel (for example, P3-1) overlaps with the virtual rectangle is greater than the area of the region where the third sub-pixel does not overlap with the virtual rectangle, or the area of the region of the third sub-pixel (for example, P3-1) that is located within the virtual rectangle is greater than the area of the region of the third sub-pixel that is located outside the virtual rectangle.

In the embodiments of the present application, in the case in which the pixel unit includes two third sub-pixels P3, by configuring that the center points of the two third sub-pixels P3 are close to the geometric center of the virtual rectangle to the largest extent, the luminescence center obtained after color mixing of the sub-pixels of the different colors of the pixel unit can approach the position of the geometric center of the pixel unit to a large extent, which improves the effect of light mixing of the sub-pixels of the different colors of the same one pixel unit to a large extent, thereby the problem of color cast is prevented, and the effect of displaying is improved.

It should be noted that, usually, because the brightnesses of the sub-pixels of the different colors of the same one pixel unit are unequal, there is a certain spacing between the geometric center of the pixel unit and the luminescence center of the pixel unit, and the luminescence center of the pixel unit is generally closer to the position of the sub-pixel having the highest brightness.

In at least one embodiment of the present application, as shown in FIG. 11, the displaying base plate further includes a plurality of data lines DL, and within the region where the same one pixel unit is located, there is a gap between the two third sub-pixels P3, and the orthographic projections of at least some of the data lines DL on the substrate fall within the region where the gap is located.

In some embodiments, the orthographic projections of the data lines DL on the substrate do not overlap with the orthographic projections on the substrate of the first sub-pixels P1, the second sub-pixels P2 and the third sub-pixel P3.

As an example, the orthographic projections of the data lines DL on the substrate do not overlap with the orthographic projections on the substrate of the anodes of the first sub-pixels P1, the second sub-pixels P2 and the third sub-pixel P3.

As an example, the opening of the pixel defining layer exposes a part of the region of the anode, wherein the region may be referred to as a pixel opening region, and the orthographic projections of the data lines DL on the substrate do not overlap with the orthographic projections on the substrate of the pixel opening regions of the first sub-pixels P1, the second sub-pixels P2 and the third sub-pixel P3.

In an exemplary embodiment, at least some of the data lines DL of the displaying base plate fall within the gaps between two neighboring third sub-pixels P3, so that there are regions where the orthographic projections on the substrate of the data lines DL and the third sub-pixels P3 do not overlap, which prevents parasitic capacitance from being generated between the data lines DL and the pixel electrodes (for example, the anodes of the OLED displaying base plate) of the sub-pixels, thereby the charging rate of the displaying base plate is increased, the brightness and the brightness uniformity of the displaying base plate is increased, and the effect of displaying while reducing the power consumption is improved.

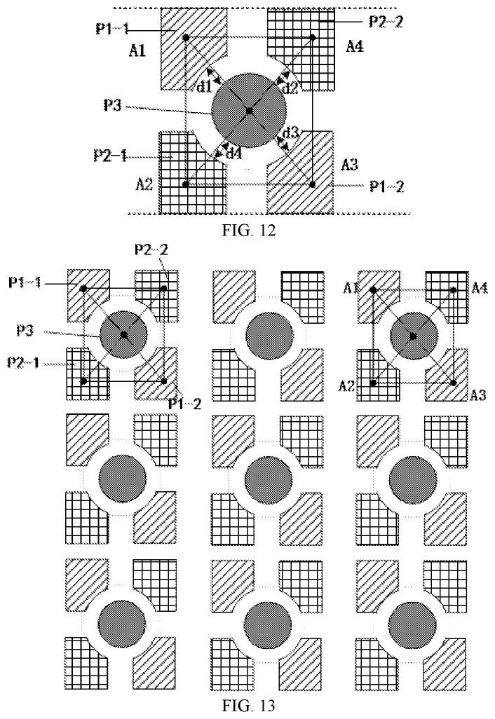

In at least one embodiment of the present application, as shown in FIGS. 12 and 13, the orthographic projection on the substrate of the intersection point of diagonal lines of the virtual quadrilateral A1A2A3A4 falls within the region of the orthographic projection of the third sub-pixel P3 on the substrate. Center points of the pixel units fall within the region where the third sub-pixel P3 is located.

In an exemplary embodiment, as shown in FIGS. 12 and 13, the orthographic projection on the substrate of the intersection point of the diagonal lines of the virtual quadrilateral A1A2A3A4 and the orthographic projection on the substrate of the center point of the third sub-pixel P3 substantially overlap.

In an exemplary embodiment, as shown in FIG. 12, the pattern of the orthographic projection of the pixel unit on the substrate is a mirror-symmetrical pattern.

In at least one embodiment of the present application, the center point of each of the pixel units shown in FIGS. 8, 10, 12 and 13 and the center point of the third sub-pixel P3 substantially coincide.

In at least one embodiment of the present application, as shown in FIGS. 12 and 13, in the direction from the center point of the third sub-pixel P3 pointing to the outer contour of the third sub-pixel P3, the distances d1, d3 from the two first sub-pixels P1 to the third sub-pixel P3 are substantially equal, the distances d2, d4 from the two second sub-pixels P2 to the third sub-pixel P3 are substantially equal, and the distances from the first sub-pixels P1 to the third sub-pixel P3 are substantially equal to the distances from the second sub-pixels to the third sub-pixel; in other words, all of d1, d2, d3 and d4 are substantially equal.

In the embodiments of the present application, by configuring that the center point of the pixel unit and the center point of the third sub-pixel P3 substantially coincide, and configuring that the distances from the first sub-pixels P1 to the third sub-pixel P3 and the distances from the second sub-pixels to the third sub-pixel are substantially equal, or, in other words, all of d1, d2, d3 and d4 are substantially equal, in this way, the luminescence center obtained by color mixing of the sub-pixels of the different colors of the pixel unit can approach the position of the geometric center of the pixel unit to a large extent, thus the effect of light mixing of the sub-pixels of the different colors of the same one pixel unit is improved to a large extent, thereby the problem of color cast is prevented, and the effect of displaying is improved.

In at least one embodiment of the present application, as shown in FIG. 12, the outer contour of the orthographic projection of the third sub-pixel P3 on the substrate is substantially circular. The outer contours of the orthographic projections of the first sub-pixels P1 and the second sub-pixels P2 on the substrate are a pattern formed by a combination of a polygon and an arc shape, and the patterns of the outer contours of the orthographic projections of the first sub-pixels P1 and the second sub-pixels P2 on the substrate are the same.

As an example, the polygon includes a triangle, a quadrangle, a pentagon, a hexagon and so on, the arc shape includes a sector shape, a circular shape, an elliptical shape, a semicircular shape, a semielliptical shape and so on, and the combination of a polygon and an arc shape includes a pattern formed by splicing a polygon and an arc shape and a pattern formed by removing part of the area from a polygon or an arc shape.

As an example, as shown in FIG. 12, the shapes of the outer contours of the orthographic projections of the first sub-pixels P1 and the second sub-pixels P2 on the substrate are a shape formed by removing a sector shape based on a rectangle.

In at least one embodiment of the present application, the areas of the orthographic projections of the two first sub-pixels P1 on the substrate are substantially equal, and the areas of the orthographic projections of the two second sub-pixels P2 on the substrate are substantially equal.

In the embodiments of the present application, by configuring that the two first sub-pixels P1 are disposed at one pair of the diagonal corners of the virtual rectangle, and the two second sub-pixels are disposed at the other pair of the diagonal corners of the virtual rectangle, and then configuring that the area of the two first sub-pixels P1 is substantially equal to the area of the two second sub-pixels P2, in this way, the luminescence center obtained by color mixing of the sub-pixels of the different colors of the pixel unit can approach the position of the geometric center of the pixel unit to a large extent, which improves the effect of light mixing of the sub-pixels of the different colors of the same one pixel unit to a large extent, thereby the problem of color cast is prevented, and the effect of displaying is improved.

In at least one embodiment of the present application, the patterns of the orthographic projections on the substrate of the at least some of the pixel units are a central symmetric pattern.

As an example, in the displaying base plate, the patterns of the orthographic projections on the substrate of some of the pixel units are a central symmetric pattern. Alternatively, the patterns of the orthographic projections on the substrate of all of the pixel units are a central symmetric pattern.

In at least one embodiment of the present application, the first sub-pixels P1 (including P1-1 and P1-2) are red sub-pixels, the second sub-pixels P2 (for example, P2-1 and P2-2) are green sub-pixels, and the third sub-pixel P3 is a blue sub-pixel.

A display panel is provided by an embodiment of the present application, wherein the display panel includes the displaying base plate stated above.

The structure of the displaying base plate may refer to the description in the preceding context, and is not discussed further herein.

The display panel may be a flexible display panel (i.e., bendable and foldable), or the display panel may be a rigid display panel.

The type of the display panel is not limited herein. It may be an organic light emitting diode (OLED) display panel or a liquid crystal display (LCD) display panel. The OLED display panel has the advantages such as a simple fabricating process, a low cost, a low power consumption, a high emitted-light brightness, a wide range of suitable operating temperature, a low volume, a high response speed, easy to realize color displaying, and large-screen displaying. Considering a broad prospect in the applications, the display panel herein is preferably the OLED display panel.

Each of the sub-pixels of the displaying base plate according to the above embodiments may further include an anode. If the anodes are formed by using a non-transparent material, then the displaying base plate may be used in top-emission-type OLED display panels, or used in top-emission-type WOLED display panels, wherein the top-emission-type OLED display panels refer to the display panels that the light rays exit from the cathode side. If the anodes are formed by using a transparent material, and the cathodes are formed by using a non-transparent material, then the OLED base plate may be used in bottom-emission-type OLED display panels, wherein the bottom-emission-type OLED display panels refer to the display panels that the light rays exit from the anode side.

In the embodiments of the present application, by configuring that each of at least some of the pixel units of the display panel includes at least five sub-pixels (the two first sub-pixels P1, the two second sub-pixels P2 and the at least one third sub-pixel P3), and by configuring that the two first sub-pixels P1 of the same color are located at the same pair of diagonal-corner positions of a virtual quadrilateral A1A2A3A4, and the two second sub-pixels P2 of the same color are located at the other pair of diagonal-corner positions of the virtual quadrilateral A1A2A3A4; and the orthographic projection of the third sub-pixel P3 on the substrate and the region circled by the orthographic projection of the virtual quadrilateral A1A2A3A4 on the substrate at least partially overlap, after color mixing of the light rays emitted by the two first sub-pixels P1 located at the same pair of diagonal corners and the two second sub-pixels P2 located at the other pair of the diagonal corners, the colors of the light rays can be neutralized, thereby the problem that color edge appears at the edge of the active area of the displaying base plate is ameliorated to a large extent, and the effect of displaying is improved.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. A displaying base plate, wherein the displaying base plate comprises a substrate, and a plurality of pixel units that are located within an active area of the substrate and are arranged in an array, and each of at least some of the pixel units comprises two first sub-pixels, two second sub-pixels and at least one third sub-pixel; and
the two first sub-pixels are located at a same pair of diagonal-corner positions of a virtual quadrilateral, and the two second sub-pixels are located at the other pair of diagonal-corner positions of the virtual quadrilateral; and an orthographic projection of the third sub-pixel on the substrate and a region circled by an orthographic projection of the virtual quadrilateral on the substrate at least partially overlap.

2. The displaying base plate according to claim 1, wherein the orthographic projection of the third sub-pixel on the substrate is located within the region circled by the orthographic projection of the virtual quadrilateral on the substrate.

3. The displaying base plate according to claim 1, wherein the orthographic projection of the third sub-pixel on the substrate and the region circled by the orthographic projection of the virtual quadrilateral on the substrate partially overlap.

4. The displaying base plate according to claim 3, wherein the virtual quadrilateral is a virtual trapezoid, the two first sub-pixels comprise a first primary sub-pixel and a first auxiliary sub-pixel, and the two second sub-pixels comprise a second primary sub-pixel and a second auxiliary sub-pixel; and
the first primary sub-pixel, the second auxiliary sub-pixel, the first auxiliary sub-pixel and the second primary sub-pixel are sequentially located at four vertex-angle positions of the virtual trapezoid, and the third sub-pixel is located at a bottom edge of the virtual trapezoid, and is disposed at a same row as the second auxiliary sub-pixel and the first auxiliary sub-pixel.

5. The displaying base plate according to claim 4, wherein the active area comprises a center region and an edge region surrounding the center region, and the edge region comprises at least one ring of sub-pixels; when the displaying base plate is displaying a frame, parts of the first auxiliary sub-pixel and the second auxiliary sub-pixel that are located within the edge region are configured to maintain a lightening state; and
parts of the first auxiliary sub-pixel and the second auxiliary sub-pixel that are located within the center region are configured to maintain a dark state; or parts of the first auxiliary sub-pixel and the second auxiliary sub-pixel that are located within the center region are configured to maintain a lightening state.

6. The displaying base plate according to claim 4, wherein the active area comprises a center region and an edge region surrounding the center region;
each of parts of the pixel units that are located within the edge region comprises two first sub-pixels, two second sub-pixels and at least one third sub-pixel; and
each of parts of the pixel units that are located within the center region comprises one first sub-pixel, one second sub-pixel and one third sub-pixel; and within the center region, the first sub-pixel, the second sub-pixel and the third sub-pixel are located sequentially at three vertex angles of a virtual triangle.

7. The displaying base plate according to claim 4, wherein an area of an orthographic projection of the first primary sub-pixel on the substrate is greater than an area of an orthographic projection of the first auxiliary sub-pixel on the substrate;
and an area of an orthographic projection of the second primary sub-pixel on the substrate is greater than an area of an orthographic projection of the second auxiliary sub-pixel on the substrate.

8. The displaying base plate according to claim 7, wherein patterns of orthographic projections of sub-pixels on the substrate comprise a polygon, an arc shape or a combination of a polygon and an arc shape; and
when the patterns of the orthographic projections of the sub-pixels on the substrate comprise the polygon, an edge of one side of the first auxiliary sub-pixel away from the second auxiliary sub-pixel and an edge of the second primary sub-pixel away from the first primary sub-pixel are substantially collinear; and an edge of one side of the second auxiliary sub-pixel away from the first auxiliary sub-pixel and an edge of one side of the first primary sub-pixel away from the second primary sub-pixel are substantially collinear.

9. The displaying base plate according to claim 3, wherein the virtual quadrilateral is a virtual rectangle, and the orthographic projection of the third sub-pixel on the substrate partially overlaps with orthographic projections on the substrate of two opposite side edges of the virtual rectangle; and
each of the pixel units comprises one third sub-pixel, and a center point of the third sub-pixel and an intersection point of diagonal lines of the virtual rectangle substantially coincide.

10. The displaying base plate according to claim 3, wherein the virtual quadrilateral is a virtual rectangle, each of the pixel units comprises two third sub-pixels, and orthographic projections of two third sub-pixels on the substrate partially overlap with orthographic projections on the substrate of two opposite side edges of the virtual rectangle; and
a center of symmetry of the two third sub-pixels and an intersection point of diagonal lines of the virtual rectangle substantially coincide.

11. The displaying base plate according to claim 10, wherein both of orthographic projections on the substrate of center points of the two third sub-pixels are located within a region circled by an orthographic projection of the virtual rectangle on the substrate.

12. The displaying base plate according to claim 10, wherein the displaying base plate further comprises a plurality of data lines, and within a region where a same pixel unit is located, there is a gap between the two third sub-pixels, and orthographic projections of at least some of the data lines on the substrate fall within a region where the gap is located.

13. The displaying base plate according to claim 2, wherein an orthographic projection on the substrate of an intersection point of diagonal lines of the virtual quadrilateral falls within a region of the orthographic projection of the third sub-pixel on the substrate; and center points of the pixel units fall within a region where the third sub-pixel is located.

14. The displaying base plate according to claim 9, wherein a center point of each of the pixel units and a center point of the third sub-pixel substantially coincide.

15. The displaying base plate according to claim 13, wherein in a direction from a center point of the third sub-pixel pointing to an outer contour of the third sub-pixel, distances from the two first sub-pixels to the third sub-pixel are substantially equal, distances from the two second sub-pixels to the third sub-pixel are substantially equal, and the distances from the first sub-pixels to the third sub-pixel are substantially equal to the distances from the second sub-pixels to the third sub-pixel.

16. The displaying base plate according to claim 13, wherein an outer contour of the orthographic projection of the third sub-pixel on the substrate is substantially circular; and outer contours of orthographic projections of the first sub-pixels and the second sub-pixels on the substrate are a pattern formed by a combination of a polygon and an arc shape, and patterns of the outer contours of the orthographic projections of the first sub-pixels and the second sub-pixels on the substrate are same.

17. The displaying base plate according to claim 9, wherein areas of orthographic projections of the two first sub-pixels on the substrate are substantially equal, and areas of orthographic projections of the two second sub-pixels on the substrate are substantially equal.

18. The displaying base plate according to claim 17, wherein patterns of orthographic projections on the substrate of the at least some of the pixel units are a central symmetric pattern.

19. The displaying base plate according to claim 1, wherein the first sub-pixels are red sub-pixels, the second sub-pixels are green sub-pixels, and the third sub-pixel is a blue sub-pixel.

20. A display panel, wherein the display panel comprises the displaying base plate according to claim 1.
